(19) United States
(12) Patent Application Publication
(10) Pub. No.: US 2026/0150227 A1
(43) Pub. Date: May 28, 2026

(54) HEAT DISSIPATION DEVICE AND ELECTRONIC DEVICE

(71) Applicant: Lenovo (Beijing) Limited, Beijing (CN)

(72) Inventor: Ji-Kai TAN, Beijing (CN)

(21) Appl. No.: 19/390,969

(22) Filed: Nov. 17, 2025

(30) Foreign Application Priority Data
Nov. 27, 2024 (CN) 202411718243.9

(51) Int. Cl. H05K 7/20

(52) U.S. Cl. CPC H05K 7/20172; H05K 7/20145

(57) ABSTRACT

A heat dissipation device and an electronic device are provided. The heat dissipation device includes a plurality of blades, a fixing component having a first surface and a second surface, and a target component having a first end connected to the plurality of blades and a second end connected to the second surface. The first surface is adjacent to the second surface and faces the plurality of blades. The first end extends toward the second end along a first direction to form the target component. At least a portion of the first direction is arranged at a target angle with respect to a target direction, where the target direction is perpendicular to the first surface and the target angle is non-zero.

### CROSS-REFERENCE TO RELATED APPLICATION

This application claims priority to Chinese Patent Application No. 202411718243.9, filed on Nov. 27, 2024, the entire content of which is incorporated herein by reference.

### TECHNICAL FIELD

The present disclosure generally relates to the field of electronic device technologies and, more particularly, to a heat dissipation device and an electronic device.

### BACKGROUND

A heat dissipation device in an electronic device is generally a fan, which drives airflow to dissipate heat from heat-generating components of the electronic device through movement of blades.

The blades used in the current fan are relatively thin, which allows them to easily deform slightly when rotating, resulting in a decrease in the fan's heat dissipation performance.

### SUMMARY

In accordance with the present disclosure, there is provided a heat dissipation device. The apparatus includes a plurality of blades, a fixing component having a first surface and a second surface, and a target component having a first end connected to the plurality of blades and a second end connected to the second surface. The first surface is adjacent to the second surface and faces the plurality of blades. The first end extends toward the second end along a first direction to form the target component. At least a portion of the first direction is arranged at a target angle with respect to a target direction, where the target direction is perpendicular to the first surface and the target angle is non-zero.

Also in accordance with the present disclosure, there is provided an electronic device. The device includes a heat-generating component and a heat dissipation device for dissipating heat on the heat-generating component. The heat dissipation device includes a plurality of blades, a fixing component having a first surface and a second surface, and a target component having a first end connected to the plurality of blades and a second end connected to the second surface. The first surface is adjacent to the second surface and faces the plurality of blades. The first end extends toward the second end along a first direction to form the target component. At least a portion of the first direction is arranged at a target angle with respect to a target direction, where the target direction is an arrangement direction of the first surface and the plurality of blades and the target angle is non-zero.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

To more clearly illustrate the technical solutions of the embodiments of the present disclosure, the drawings needed for use in the description of the embodiments will be briefly introduced below. The drawings described below are some embodiments of the present disclosure. For those of ordinary skill in the art, other drawings can be obtained according to these drawings without any creative work. Throughout the drawings, the same or similar reference numerals represent the same or similar elements. It should be understood that the drawings are schematic and that the originals and elements are not necessarily drawn to scale.

FIG. 1 is a front view of an exemplary heat dissipation device consistent with various embodiments of the present disclosure.

FIG. 2 is a side view of an exemplary heat dissipation device consistent with various embodiments of the present disclosure.

FIG. 3 is a partially enlarged view of an S part in FIG. 2 of a heat dissipation device consistent with various embodiments of the present disclosure.

FIG. 4 is a schematic structural diagram of a first direction consistent with various embodiments of the present disclosure.

FIG. 5 is a schematic diagram of an airflow velocity distribution diagram when the first direction is direction “g” in FIG. 4 consistent with various embodiments of the present disclosure.

FIG. 6 is a schematic diagram of an airflow velocity distribution diagram when the first direction is direction “e” in FIG. 4 consistent with various embodiments of the present disclosure.

FIG. 7 is a schematic diagram of a three-dimensional structure of an exemplary first heat dissipation device consistent with various embodiments of the present disclosure.

FIG. 8 is a schematic diagram of another three-dimensional structure of an exemplary first heat dissipation device consistent with various embodiments of the present disclosure.

FIG. 9 is a partially enlarged view of an A part in FIG. 8 of a heat dissipation device consistent with various embodiments of the present disclosure.

FIG. 10 is a schematic diagram of a first position between an exemplary first heat dissipation device and a heat-generating component consistent with various embodiments of the present disclosure.

FIG. 11 is a schematic diagram of an airflow speed distribution when an exemplary first heat dissipation device and a heat-generating component are in a first position consistent with various embodiments of the present disclosure.

FIG. 12 is a schematic diagram of a second position between an exemplary first heat dissipation device and a heat-generating component consistent with various embodiments of the present disclosure.

FIG. 13 is a schematic diagram of an airflow speed distribution when an exemplary first heat dissipation device and a heat-generating component are in a second position consistent with various embodiments of the present disclosure.

FIG. 14 is a front view of another exemplary heat dissipation device consistent with various embodiments of the present disclosure.

FIG. 15 is a side view of another exemplary heat dissipation device consistent with various embodiments of the present disclosure.

FIG. 16 is a front view of another exemplary heat dissipation device consistent with various embodiments of the present disclosure.

FIG. 17 is a schematic diagram of a three-dimensional structure of another exemplary heat dissipation device consistent with various embodiments of the present disclosure.

FIG. 18 is a front view of another exemplary heat dissipation device consistent with various embodiments of the present disclosure.

FIG. 19 is a schematic diagram of a three-dimensional structure of another exemplary heat dissipation device consistent with various embodiments of the present disclosure.

FIG. 20 is a front view of another exemplary heat dissipation device consistent with various embodiments of the present disclosure.

FIG. 21 is a schematic diagram of a three-dimensional structure of another exemplary heat dissipation device consistent with various embodiments of the present disclosure.

FIG. 22 is a front view of another exemplary heat dissipation device consistent with various embodiments of the present disclosure.

### DETAILED DESCRIPTION OF THE EMBODIMENTS

The present disclosure provides a heat dissipation device and an electronic device.

Specific embodiments of the present disclosure are hereinafter described with reference to the accompanying drawings. The embodiments described are merely examples of the present disclosure and should not be regarded as limitations of this application. All other embodiments obtained by those of ordinary skill in the art without creative efforts fall within the scope of protection of the present disclosure.

Unless otherwise defined, all technical and scientific terms used in the present disclosure have the same meaning as those generally understood by those skilled in the art to which the present disclosure belongs. The terms used herein are only for the purpose of describing the present disclosure and are not intended to limit the scope of the present disclosure.

In the following description, “some embodiments”, “this embodiment”, one embodiment”, and “examples”, etc., describe subsets of all possible embodiments. But it is understood that “some embodiments” can be the same subset or different subsets of all possible embodiments and can be combined with each other without conflict.

In the following description, the terms “first/second/third” or similar terms involved are only used to distinguish similar objects, and do not represent a specific order for the objects. It is understandable that items described by “first/second/third” may be interchanged with a specific order or sequence where permitted, such that the present disclosure described here can be implemented in an order other than that illustrated or described here.

In the present disclosure, the term “and/or” is only a kind of association relationship describing associated objects, indicating that there can be three types of relationships. For example, “object A and/or object B” may represent object A exists alone, object A and object B exist at the same time, or object B exists alone. The terms “including”, “comprising”, “having”, and any variations thereof, are intended to cover a non-exclusive inclusion, such that a process, method, system, product, or apparatus that comprises a list of elements is not necessarily limited to those elements but may include other elements not expressly listed or inherent to such process, method, product, or apparatus.

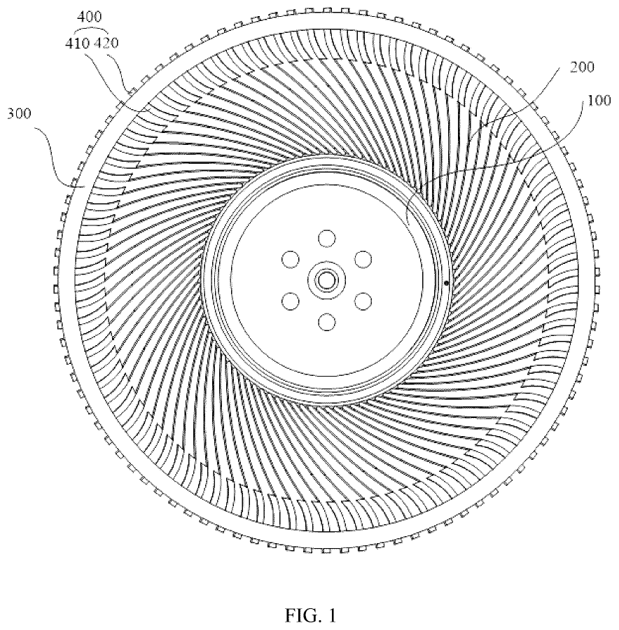

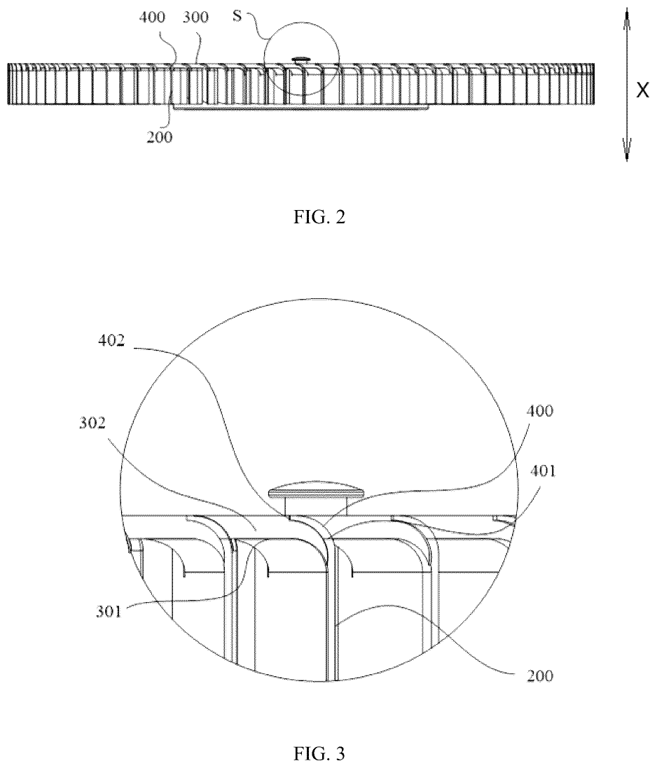

The present disclosure provides a heat dissipation device. As shown in FIG. 1 to FIG. 7, in one embodiment of the present disclosure, the heat dissipation device may include a plurality of blades 200, a fixing component 300, and a target component 400.

The fixing component 300 may have a first surface 301 and a second surface 302. The first surface 301 may be adjacent to the second surface 302 and may face the plurality of blades 200. The fixing component 300 may be directly or indirectly connected to a rotor component 100 or the plurality of blades 200, thereby enhancing the bending resistance of the plurality of blades 200. In one embodiment, the plurality of blades 200 are blades of a fan for heat dissipation.

A first end 401 of the target component 400 may be connected to the plurality of blades 200, and a second end 402 of the target component 400 may be connected to the second surface 302. Since the first surface 301 and the second surface 302 are adjacent to each other, the first surface 301 and the second surface 302 may be arranged at an angle. That is, the target component 400 may connect to the plurality of blades 200 and the second surface 302 of the fixing component 300, which is arranged at an angle to the first surface 301.

The first end 401 may extend toward the second end 402 along a first direction to form the target component 400. At least a portion of the first direction may be arranged at a target angle with a target direction X. The target direction X may be perpendicular to the first surface 301, where the target angle is not 0°.

It should be noted that the target component 400 includes an end (the second end 402) connected to the second surface 302 and an end (the first end 401) connected to the plurality of blades 200. A structure formed by extending from these two ends (the first end 401 and the second end 402) may be the target component 400. A minimum distance between the first end 401 and the second end 402 may be a straight line, but this does not mean that the target component 400 is a straight-line structure. Any path may be formed by extending from the first end 401 to the second end 402. The extension may not be a straight line but rather extend along the first direction. That is, the aforementioned extension does not only include the direct extension from the first end 401 to the second end 402. It may be any structure extending along the first direction from the first end 401 (the end connected to the blade 200) to the second end 402 (the end connected to the second surface 302), which is the target component 400. Further, at least a portion of the first direction may include all of the first direction or a portion of the first direction. The portion of the first direction may be a structure in the first direction close to the first end 401, close to the second end 402, or in the middle of the first direction.

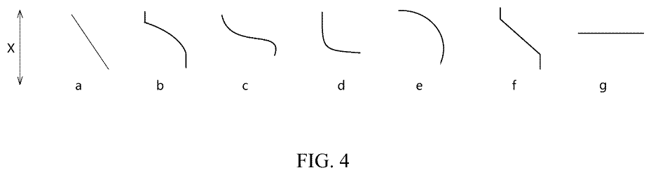

The first direction may be a linear direction, that is, a direction extending from the first end 401 to the second end 402 of the target component 400 may be a linear direction. For example, direction a, as shown in FIG. 4, is the first direction, i.e., the first direction is a linear direction set at a target angle with respect to the target direction X.

The first direction may also be a non-linear direction, such as a composite direction including any arc and/or straight lines. For example, the directions b, c, d, e, and f, as shown in FIG. 4, may all serve as the first direction. At least a portion of the first direction may be set at a target angle with respect to the target direction X. The portion set at the target angle with respect to the target direction X may be a straight line or an arc. For example, the direction “b” includes two straight lines and an arc, where the straight lines are parallel to the target direction X and the arc connects the two straight lines. Therefore, the arc may be set at the target angle with respect to the target direction X. Of course, the first direction may also be set to other directions, which are not listed here and are all within the scope of the present disclosure.

The target component 400 may be integrally formed with the plurality of blades 200 and the fixing component 300, to achieve the effect of connecting the target component 400 to the plurality of blades 200 and the fixing component 300. In the integrally formed structure, the end of the target component 400 that is separated from the second surface 302 of the target component 400 may be the first end 401. That is, the first end 401 may protrude from the second surface 302. Alternatively, in some other embodiments, the target component 400 may be integrally formed with the plurality of blades 200, and the target component 400 and the fixing component 300 may be connected by assembly (e.g., gluing, welding, or a concave-convex fit).

In yet some other embodiments, the target component 400 may be integrally formed with the fixing component 300, and the target component 400 and the plurality of blades 200 may be connected by assembly (e.g., gluing, welding, or a concave-convex fit).

In yet some other embodiments, the target component 400, the plurality of blades 200, and the fixing component 300 may be manufactured separately, and the target component 400, the plurality of blades 200, and the fixing component 300 may be connected by assembly (e.g., gluing, welding, or a concave-convex fit).

In the heat dissipation device provided in the embodiments of the present application, the first end 401 of the target component 400 may be connected to the plurality of blades 200, and the second end 402 of the target component 400 may be connected to the second surface 302. This may allow the plurality of blades 200 to be indirectly connected to the fixing component 300 through the target component 400. That is, at least one plurality of blades 200 may be connected to the fixing component 300 through the target component 400, and the portion where the plurality of blades 200 and the target component 400 are connected may be indirectly connected to the same fixing component 300, improving the positional stability of the portion where the plurality of blades 200 and the target component 400 are connected relative to the fixing component 300. When the rotor component 100 drives the plurality of blades 200 to rotate, the portion where the plurality of blades 200 and the target component 400 are connected may be supported by the fixing component 300 through the target component 400, reducing the displacement of the portion where the plurality of blades 200 and the target component 400 are connected to the overall structure of the heat dissipation device, effectively strengthening the plurality of blades 200's anti-deformation strength and reducing the amount of deformation of the plurality of blades 200 caused by airflow, thereby ensuring the performance of the heat dissipation device.

Since the first surface 301 may be adjacent to the second surface 302, the first surface 301 and the second surface 302 may be arranged at an angle, with the first surface 301 facing the blade 200. Therefore, the second surface 302 may be arranged at an angle to a side of the plurality of blades 200 facing the fixing component 300 (the side opposite the first surface 301). The target direction X may be the arrangement direction of the first surface 301 and the plurality of blades 200, that is, target direction X may be the thickness direction of the fixing component 300. Since the first end 401 may extend toward the second end 402 along the first direction to form target component 400, and at least a portion of the first direction may be arranged at the target angle with respect to the target direction X, the dimension of the target component 400 along the first direction may be increased while maintaining a constant thickness of the fixing component 300, thereby increasing the connection area between the target component 400 and the fixing component 300 and further improving the stability of the connection between the target component 400 and the fixing component 300. Therefore, the support effect achieved at the connection between the plurality of blades 200 and the target component 400 may be further enhanced, thereby further strengthening the deformation resistance of the plurality of blades 200.

At least a portion of the first direction may be curved.

In some embodiments, the entire first direction may be curved. As shown in FIG. 4, in one embodiment, the directions c and e may be entirely curved. The direction “c” may be formed by connecting two curves with opposite curvatures, forming an “S” shape. At least a portion of the two curves may be set at a target angle with respect to the target direction X. The direction “e” may include a single curve, which may be set at a target angle with respect to the target direction X.

In other embodiments, a portion of the first direction may be curved, while another portion may be non-curved (such as a straight line or a zigzag line). As shown in FIG. 4, the directions b and d may be structures formed by combining a portion of a curve and another portion of a straight line. The direction “b” includes a first straight line, a first curve, and a second straight line connected in sequence. The first straight line and the second straight line may be relatively parallel and arranged along the target direction X. The first curve may be set at a target angle with respect to the target direction X. The direction “d” includes a third straight line, a second curve, and a fourth straight line connected in sequence. The third straight line may be relatively perpendicular to the fourth straight line and may be arranged along the target direction X. The second curve may be arranged at a target angle to the target direction X.

In the above embodiment, since the curved portion may be arranged at the target angle with respect to the target direction X, the connection area between the target component 400 and the second surface 302 may be increased, thereby improving the stability of the overall structure formed by the plurality of blades 200, the target component 400, and the fixing component 300, and further enhancing the deformation resistance of the plurality of blades 200.

Further, compared to a straight line arranged at the target angle with respect to the target direction X, this may effectively avoid the target component 400 and the plurality of blades 200 from being arranged at an angle, effectively preventing noise caused by factors such as vortices generated at the angle to further reduce noise.

Using the direction “a” as the first direction as an example, the first end 401 may extend toward the second end 402 along the direction “e” to form the target component 400, forming a straight plate. The first end 401 of the target component 400 may be connected to the plurality of blades 200, resulting in an angled connection between the target component 400 and the plurality of blades 200. This angled connection may be prone to vortices, which may generate noise and lead to stress concentration.

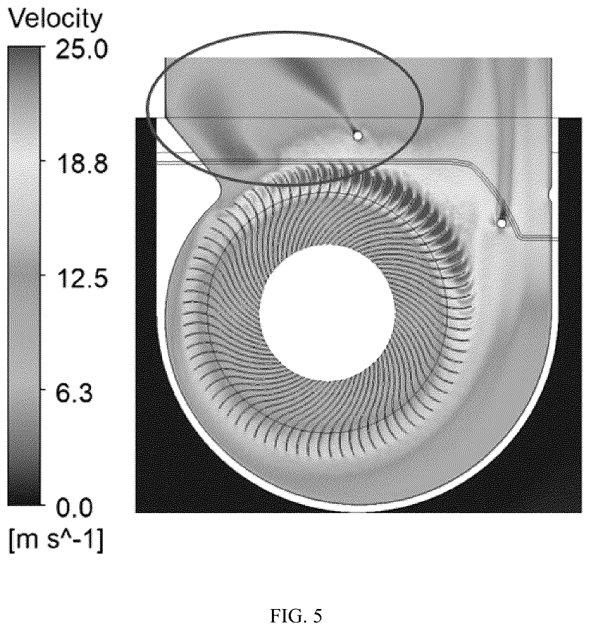

In some embodiments, the target angle may be 90°. Using the direction g as the first direction as an example, the direction g may be perpendicular to the target direction X. The first end 401 may extend toward the second end 402 along the direction “e” to form the target component 400, making the target component 400 a straight plate. The first end 401 of the target component 400 may be connected to the plurality of blades 200, resulting in an angled connection between the target component 400 and the plurality of blades 200. This angled connection may be prone to generating vortices, which may cause noise and stress concentration. Further, since the direction “g” may be perpendicular to the target component 400, the target component 400 may only serve to strengthen the deformation resistance of the plurality of blades 200 and may have little or no effect on the airflow, not increasing airflow. As shown in FIG. 5, the airflow velocity distribution diagram shows that in embodiments where the target component 400 may be a straight plate perpendicular to the target direction X (the axis of the rotor component 100), there may be more blue areas with slower airflow.

In some embodiments, the target angle may not be 90°. The direction “a” shown in FIG. 4 may be the first direction.

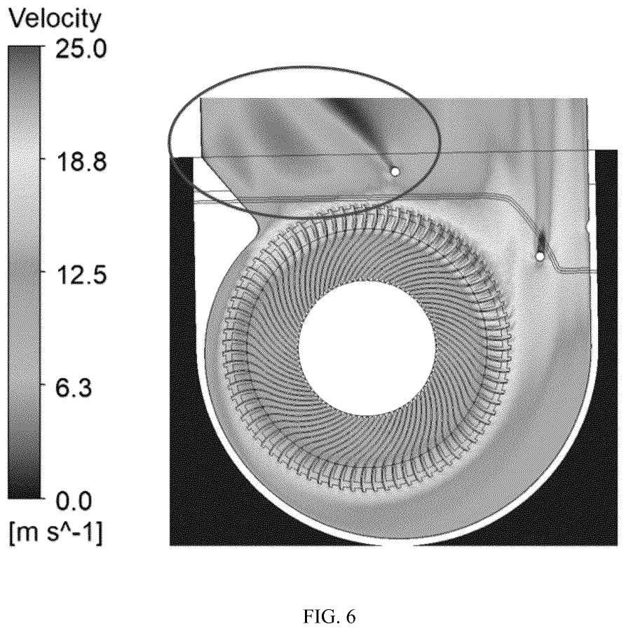

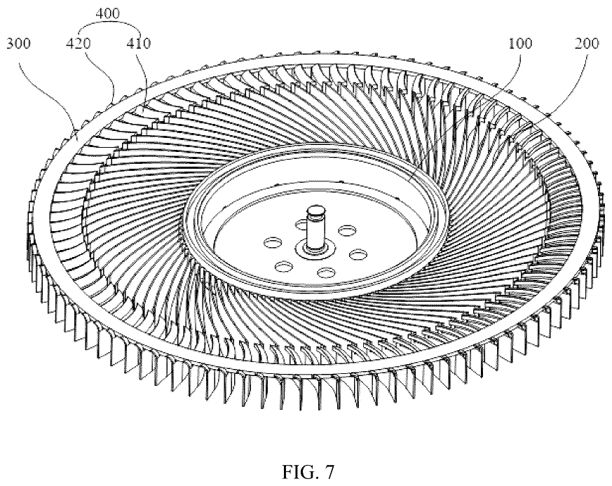

Using the direction “e” as the first direction for illustration, the first end 401 may extend toward the second end 402 along the direction “e” to form the target component 400, making the target component 400 a curved plate. The first end 401 of the target component 400 may be connected to the plurality of blades 200, resulting in an arc-shaped connection between the target component 400 and the plurality of blades 200. This may avoid angles that could create vortices, effectively reducing noise. This may also prevent stress concentration at the connection between the target component 400 and the plurality of blades 200, thereby increasing service life. Further, since the target component 400 may be a curved plate, it may have a curved surface on the same side as the windward surface of the plurality of blades 200. This curved surface may serve as an auxiliary windward surface, driving airflow and increasing airflow. As shown in FIG. 6, the airflow velocity distribution diagram shows that in the embodiments where the target component 400 is a curved plate, there may be fewer blue areas with slower airflow. This may result in a greater overall flow rate for the heat dissipation device than in the embodiments where the target component 400 is a straight plate and perpendicular to the target direction X shown in FIG. 5.

In some other embodiments, alternatively, the first direction may be a zigzag line formed by connecting multiple straight lines. As shown in FIG. 4, the direction “f” includes a fifth, sixth, and seventh straight lines connected in sequence. The fifth and seventh straight lines may be relatively parallel and arranged along the target direction X, and the sixth straight line may be arranged at the target angle to the target direction X.

In some embodiments, the curvature of the curve may be convex away from the plurality of blades 200. As shown in FIG. 3, the curvature of the curve may be convex away from the plurality of blades 200, resulting in the target component 400 having a concave curved surface facing the airflow gap between two adjacent blades 200. As the rotor component 100 drives the plurality of blades 200 to rotate, the concave curved surface may rotate along the axis of the rotor component 100, and the airflow flowing toward the target component 400 may converge on the concave curved surface, facilitating the direction of the airflow.

In other embodiments, the curvature of the curve may be convex toward the plurality of blades 200, resulting in the target component 400 having a convex curved surface facing away from the airflow gap between two adjacent blades 200. As the rotor component 100 rotates the plurality of blades 200, the convex curved surface may avoid direct collisions with the airflow flowing toward it, reducing kinetic energy loss during the flow.

In some embodiments, the first end 401 of the target component 400 may be connected to the edge of the plurality of blades 200 facing the fixing component 300. The edge of the plurality of blades 200 facing the fixing component 300 may be either the upper or lower edge of the plurality of blades 200. Between two adjacent blades 200, the second end 402 of the target component 400 connected to one of the plurality of blades 200 may be spaced apart from the others of the plurality of blades 200. This arrangement may create a gap between the portions of the adjacent blades 200 connecting to the target component 400. In other words, fluid within the gap formed between the adjacent blades 200 may pass through the portion of the adjacent blades 200 connecting to the target component 400. This may reduce the material consumption of the heat dissipation device, avoid excessive weight because of excessive material consumption, and ensure the performance of the heat dissipation device.

The portions of two adjacent blades 200 that are connected to the target component 400 may also be connected through the target component 400, to enhance the deformation resistance of the plurality of blades 200.

In some embodiments, each blade 200 of the plurality of blades may include a first portion 210 and a second portion 220 arranged in a direction away from the rotor component 100, and the target component 400 may be connected to the second portion 220. Since the first portion 210 of the blade 200 is located close to the rotor component 100, during the rotation of the blade 200 driven by the rotor component 100, while the blade 200 is connected to the rotor component 100, the deformation of the first portion 210 may be less than that of the second portion 220. The connection between the target component 400 and the second portion 220 may provide support for the areas of the blade 200 with greater deformation, further reducing deformation of the blade 200.

As shown in FIG. 6, the thickness of the first portion 210 may be less than that of the second portion 220, with the thickness direction being along the axis of the rotor component 100. With this arrangement, the windward area of the second portion 220 may be larger than the windward area of the first portion 210 per unit dimension along the radial direction of the heat dissipation device. Without the target component 400, the deformation of the second portion 220 may be further increased compared to the deformation of the first portion 210. Therefore, by connecting the target component 400 to the second portion 220, the deformation resistance of the blade 200 may be ensured while maintaining the performance of the heat dissipation device.

In some embodiments, the second portion 220 may be recessed away from the windward side of the blade 200, while the first portion 210 may be convex toward the windward side of the blade 200. This arrangement may create an “S” shape for the blade 200 as it moves away from the center of the heat dissipation device, thereby ensuring the performance of the heat dissipation device. For example, this may reduce airflow vibration, thereby reducing noise, and may increase the surface area of the blade 200 per unit dimensions along the radial direction of the heat dissipation device, thereby enhancing heat dissipation.

In some embodiments, the first surface 301 may be connected to second portions 220 of the plurality of blades 200. The deformation of the first portion 210 may be smaller than that of the second portion 220. Therefore, the first surface 301 and the second portions 220 of the plurality of blades 200 may provide support and reinforcement for the fixing component 300 and the plurality of blades 200 at positions with greater deformation, further enhancing the deformation resistance of the plurality of blades 200.

The fixing component 300 may be connected to a first position on the second portion 220, and the target component 400 may be connected to a second position on the second portion 220. The first and second positions may be different positions on the second portion 220 and arranged in a direction toward and away from the rotor component 100 respectively. That is, the fixing component 300 and the target component 400 (indirectly connected to the fixing component 300) may be connected to different positions of the second portion 220 of the blade 200, and the first position where the fixing component 300 is connected to the second portion 220 and the second position where the target component 400 is connected to the second portion 220 may be arranged in a direction close to and away from the rotor component 100, such that the second portion 220 is respectively connected to the fixing component 300 and the target component 400 at different positions along the radial direction of the heat dissipation device, thereby further improving the deformation resistance of the second portion 220 of the blade 200.

The fixing component 300 may be an annular component, with its centerline coinciding with the axis of the rotor component 100. When the plurality of blades 200 may be connected to the fixing component 300, the combined structure of the rotor component 100, the plurality of blades 200, and the fixing component 300 of the heat dissipation device may form a centrally symmetrical structure, which facilitates stable rotation of the heat dissipation device.

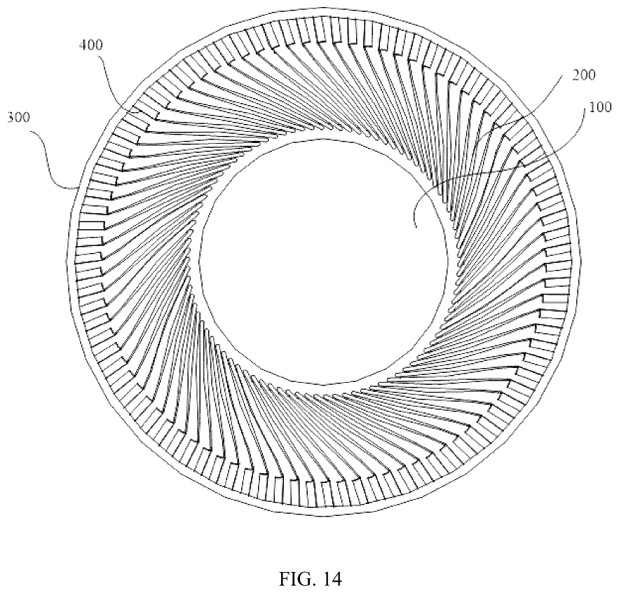

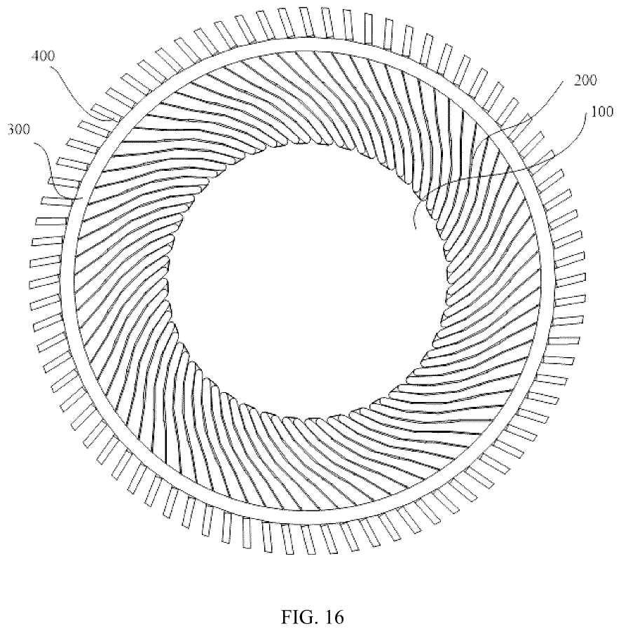

As shown in FIG. 1, FIG. 14, and FIG. 16, in some embodiments, the target component 400 may connect the windward surface of the plurality of blades 200 to the fixing component 300. Therefore, the fixing component 300 may have a surface facing the same direction as the windward surface of the plurality of blades 200, which serves as an auxiliary windward surface for contact with the airflow, further increasing airflow.

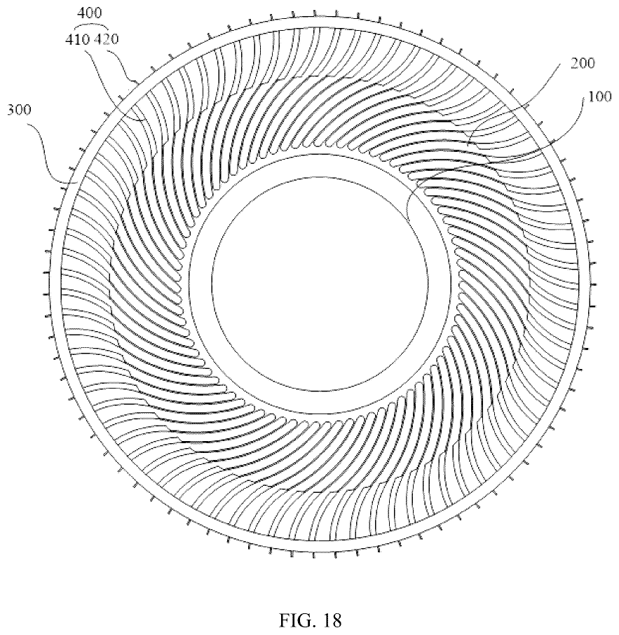

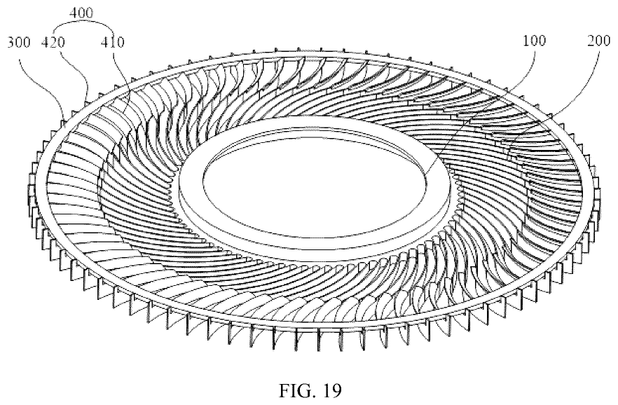

As shown in FIG. 18 and FIG. 19, in some other embodiments, the target component 400 may connect the leeward surface of the blade 200 to the fixing component 300. In other words, the target component 400 may serve as a supporting structure between the leeward surface of the blade 200 and the fixing component 300, enhancing the support provided by the target component 400 to the blade 200.

In one embodiment, the heat dissipation device may function as a centrifugal impeller. That is, as the heat dissipation device rotates along its axis, airflow may enter the center of the heat dissipation device and exit along its periphery, with the direction of exit perpendicular to the axis. Therefore, a device being cooled by the heat dissipation device (such as the heat-generating component 600) may be located on the periphery of the heat dissipation device perpendicular to the axis of the heat dissipation device. This may restrict the relative position of the heat dissipation device and the device being cooled.

To address this issue, the target component 400 may include a guide surface that faces the airflow gap between two adjacent blades 200 and may not be perpendicular to the axis of the rotor component 100. As the rotor component 100 drives the plurality of blades 200 to rotate, the guide surface may rotate along the axis of the rotor component 100, driving the fluid in the airflow gap along the axis of the rotor component 100, thereby directing the fluid away from the target component 400. In other words, the guide surface of the target component 400 may direct the airflow, preventing it from exiting the heat dissipation device in a direction perpendicular to the axis of the rotor component 100.

Since the guide surface of the target component 400 may be non-perpendicular to the axis of the rotor component 100 and face the airflow gap between two adjacent blades 200, it may act like the windward surface of an axial flow fan. As the rotor component 100 drives the plurality of blades 200 to rotate, the guide surface may drive the airflow in the airflow gap along the axial direction of the heat dissipation device (the axis of the rotor component 100). Combined with the centrifugal force of the plurality of blades 200, the airflow may flow away from the rotor component 100 at a certain angle to the axis of the rotor component 100. As shown in FIG. 3, in this embodiment, the guide surface of the target component 400 may be a concave arc surface of the target component 400. Of course, other configurations may also be possible in some other embodiments and will not be specifically limited here.

Each blade 200 of the plurality of blades 200 may include a first edge and a second edge, and the first and second edges may be arranged in the direction of the axis of the rotor component 100. The fixing component 300 may be connected to the first edge of the blade 200, the second edge of the blade 200, or the middle position of the blade 200, with the middle position being located between the first and second edges.

In one embodiment, the first edge may be the upper edge of the blade 200, and the second edge may be the lower edge of the blade 200. Therefore, for a centrifugal impeller, the upper and lower edges may be aligned along the axis. Therefore, the fixing component 300 may be connected to the first edge of the blade 200, i.e., the fixing component 300 may be connected to the upper edge of the blade 200. To prevent the fixing component 300 from increasing the overall thickness of the heat dissipation device, the third surface of the fixing component 300, opposite to the first surface, may be aligned or coplanar with the upper edge of the blade 200.

In some other embodiments, the fixing component 300 may be connected to the second edge of the blade 200, i.e., the fixing component 300 may be connected to the lower edge of the blade 200. In some other embodiments, the fixing component 300 may also connect to the middle position of the blade 200. That is, between two adjacent blades 200, the fixing component 300 may connect the windward side of one blade 200 to the leeward side of another blade 200.

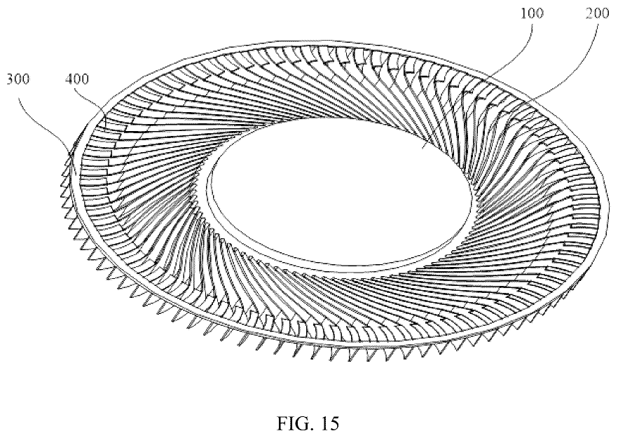

As shown in FIG. 14 and FIG. 15, in some embodiments, the second surface 302 may be a side of the fixing component 300 facing the rotor component 100, and the target component 400 may connect the portion of the blade 200 located between the fixing component 300 and the rotor component 100 to the second surface 302. That is, the target component 400 may be located on the side of the fixing component 300 facing the center of the heat dissipation device.

As shown in FIG. 14 and FIG. 15, the target component 400 may connect the windward side of the blade 200 to the fixing component 300. Alternatively, the target component 400 may connect the leeward side of the blade 200 to the fixing component 300.

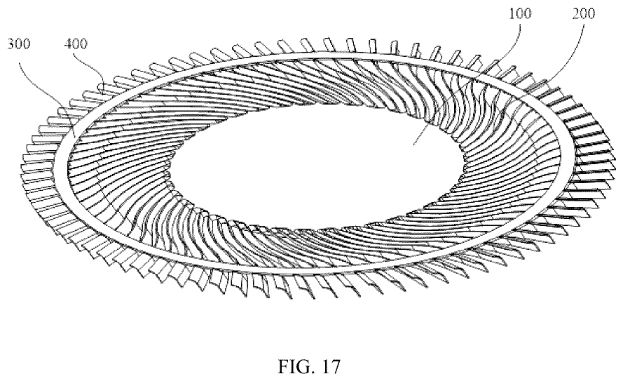

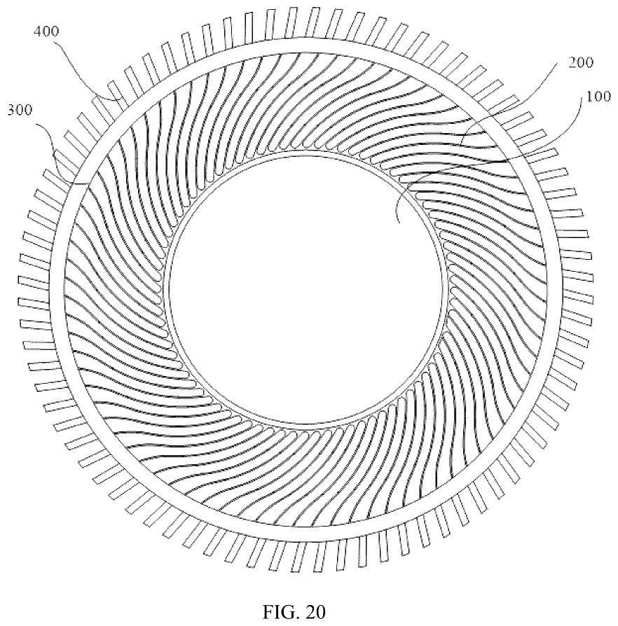

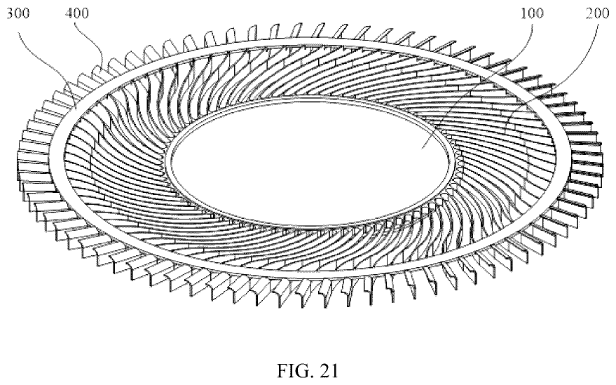

As shown in FIG. 16, FIG. 17, FIG. 20, and FIG. 21, in some other embodiments, the second surface 302 may be a side of the fixing component 300 facing away from the rotor component 100, and the target component 400 may connect the portion of the blade 200 located on the fixing component 300 away from the rotor component 100 to the second surface 302.

As shown in FIG. 16 and FIG. 17, the target component 400 may connect the windward side of the blade 200 to the fixing component 300. As shown in FIG. 20 and FIG. 21, the target component 400 may connect the leeward side of the blade 200 to the fixing component 300.

As shown in FIG. 1, FIG. 7, FIG. 18, and FIG. 19, in some other embodiments, the second surface 302 may include a first sub-surface of the fixing component 300 facing the rotor component 100 and a second sub-surface of the fixing component 300 facing away from the rotor component 100. The target component 400 may include a first reinforcement 410 and a second reinforcement 420. The first reinforcement 410 may connect a portion of the blade 200 located between the fixing component 300 and the rotor component 100 to the first sub-surface, while the second reinforcement 420 may connect a portion of the blade 200 located on the fixing component 300 away from the rotor component 100 to the second sub-surface.

As shown in FIG. 1 and FIG. 7, the target component 400 may connect the windward surface of the blade 200 to the fixing component 300. As shown in FIG. 18 and FIG. 19, the target component 400 may connect the leeward surface of the blade 200 to the fixing component 300.

The first projection area of the target component 400 along the second direction may be located within the second projection area of the fixing component 300 along the second direction. The second direction may be perpendicular to the axis of the rotor component 100. That is, the second direction may be the radial direction of the heat dissipation device. The axial dimension of the target component 400 may not exceed the axial dimension of the fixing component 300, thereby facilitating the demolding of the target component 400 and the fixing component 300 as a single-piece structure. Further, a portion of the target component 400 located on the side of the fixing component 300 facing away from the blade 200 may not contribute to the deformation resistance of the blade 200. Therefore, ensuring that the axial dimension of the target component 400 does not exceed the axial dimension of the fixing component 300 may also avoid material waste.

As shown in FIG. 7, to further prevent stress concentration, the first surface 301 may be connected to the plurality of blades 200. A rounded corner structure 310 may be provided at the connections between the first surface 301 and the plurality of blades 200, and the target component 400 may be connected to the rounded corner structure 310.

In one embodiment, where the target component 400 is a curved plate, the diameter of the rounded corner structure 310 may be smaller than the minimum diameter of the target component 400's connection surface for connection to the rounded corner structure 310.

As shown in FIG. 1, FIG. 5, and FIG. 6, the fixing component 300 may extend a certain length along the blade 200. The fixing component 300 may be connected only to the second portion 220 of the fixing component 300. Alternatively, the fixing component 300 may be connected only to the first portion 210 of the fixing component 300. Alternatively, the fixing component 300 may be connected between the first and second portions 210, 220 of the fixing components 300, or to both the first and second portions 210, 220 of the fixing component 300. Further, the fixing component 300 may be positioned along the blade 200 toward the center of the heat dissipation device, connecting the fixing component 300 to the rotor component 100.

As shown in FIG. 10, the heat dissipation device may have a first side 001 and a second side 002 that may be aligned and opposite to each other along the axis of the rotor component 100. The arrangement direction of the target position 500 and the heat dissipation device may be perpendicular to the axis of the rotor component 100. The target position 500 may have a third side 003 corresponding to the first side 001 and a fourth side 004 corresponding to the second side 002.

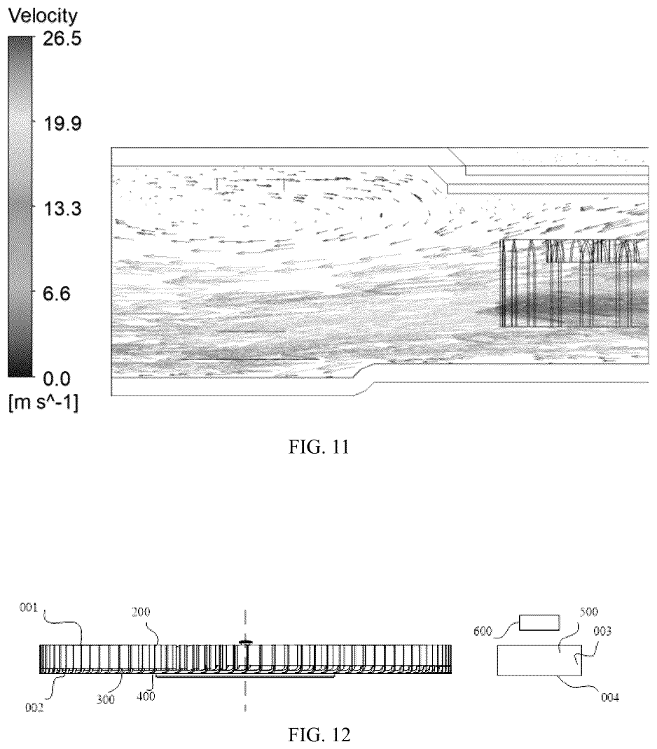

The target component 400 may be connected to the blade 200 near the first side 001. During the rotation of the blade 200, it may drive airflow toward the area on the fourth side 004 of the target position 500. As shown in FIG. 11, the airflow velocity distribution diagram shows that the target component 400 may be connected to the blade 200 near the first side 001 (e.g., the upper edge of the blade 200). The red area with faster airflow may be near the second side 002 of the heat dissipation device. Since the second side 002 corresponds to the fourth side 004, the heat dissipation device may better dissipate heat from the heat-generating component 600 located on the fourth side 004 of the target position 500.

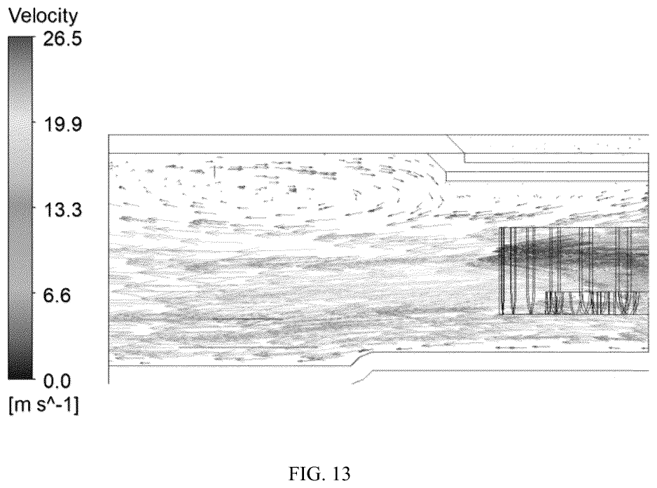

As shown in FIG. 12, in some other embodiments, the target component 400 may also be connected to the blade 200 near the second side 002. During the rotation of the blade 200, it may drive airflow toward the third side 003 of the target position 500. As shown in FIG. 13, the airflow velocity distribution diagram shows that the target component 400 may be connected to the blade 200 near the second side 002 (e.g., the lower edge of the blade 200). The red area with faster airflow may be near the first side 001 of the heat dissipation device. Since the second side 001 corresponds to the third side 003, the heat dissipation device may better dissipate heat from the heat-generating component 600 located on the third side 003 of the target position 500.

Through this arrangement, the position of the target component 400 may be adjusted to meet the heat dissipation requirements of the device being cooled by the heat dissipation device (e.g., the heat-generating component 600) located on the third side 003 or the fourth side 004 of the target position 500. This may eliminate the need for the device being cooled by the heat dissipation device (e.g., the heat-generating component 600) to be located at the target position 500 to achieve optimal heat dissipation, reduce the relative positional constraints between the heat dissipation device and the device being cooled, and allow for more flexible placement of the heat dissipation device and the device being cooled.

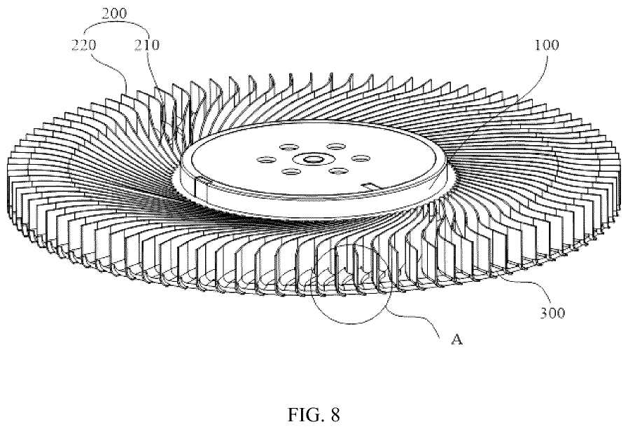

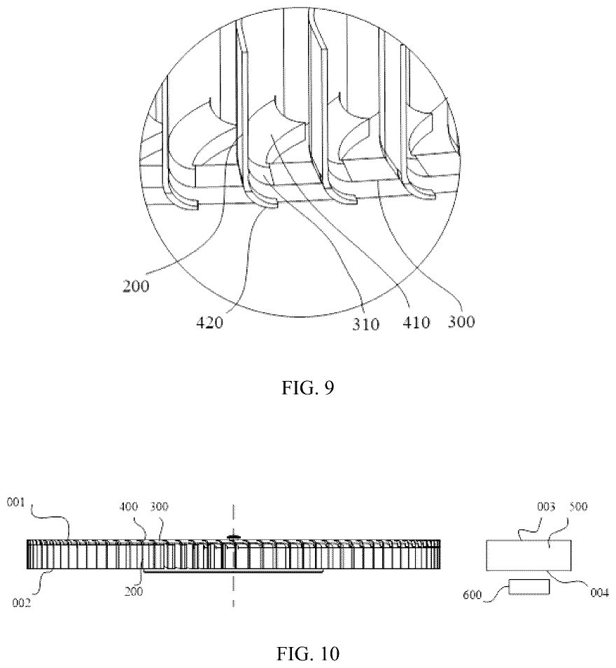

As shown in FIG. 1 to FIG. 21, in some embodiments, the heat dissipation device may further include the rotor component 100 that may be rotatable along its axis, and the plurality of blades 200 may be arranged circumferentially around the rotor component 100. That is, the rotor component 100 may be directly connected to the plurality of blades 200, thereby driving the plurality of blades 200 to rotate along the axis of the rotor component 100.

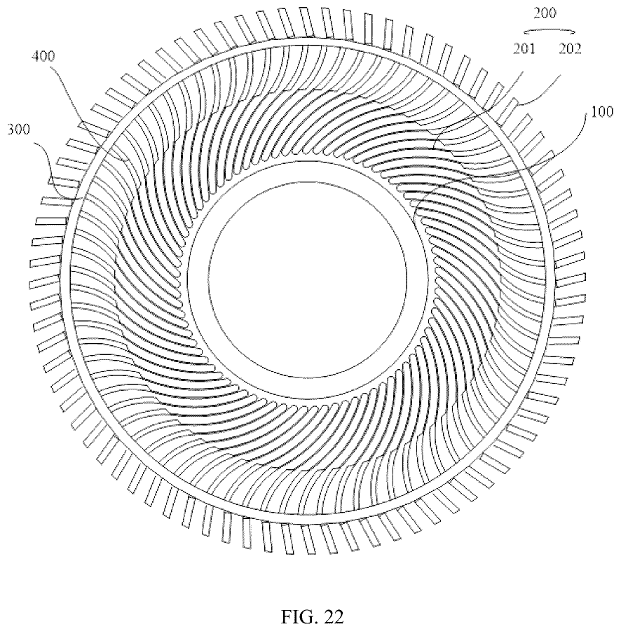

As shown in FIG. 22, in some embodiments, the heat dissipation device may further include a rotor component 100. The rotor component 100 may be capable of rotating along its axis, and the plurality of blades 200 may be arranged circumferentially around the rotor component 100. For example, the rotation of the rotor component 100 along its axis may drive the plurality of blades 200 to rotate along their axis, causing the plurality of blades 200 to drive airflow away from the rotor component 100, thereby centrifuging the airflow.

In some embodiments, the plurality of blades 200 may include first blades 201 and second blades 202. The first blades 201 may connect the rotor component 100 to the fixing component 300, and the second blades 202 may connect to the fixing component 300. The first blades 201 and the second blades 202 may be separate blades, and the second blades 202 may not be directly connected to the rotor component 100.

In some embodiments, one first blade 201 may be connected to a first position of the fixing component 300, and one second blade 202 may be connected to a second position of the fixing component 300. The first position and the second position may be located on different sides of the fixing component 300. First positions and second positions may be staggered.

The present disclosure also provides an electronic device including a heat-generating component 600 and a heat dissipation device for dissipating heat from the heat-generating component 600.

The heat dissipation device may include a plurality of blades 200, a fixing component 300, and a target component 400. The plurality of blades 200 may be arranged along the circumference of a rotor component 100. The fixing component 300 may include a first surface 301 and a second surface 302, with the first surface 301 adjacent to the second surface 302 and facing the plurality of blades 200. The target component 400 may include a first end 401 connected to the plurality of blades 200 and a second end 402 connected to the second surface 302. The first end 401 may extend toward the second end 402 along a first direction to form the target component 400. At least a portion of the first direction may be arranged at a target angle with respect to a target direction. The target direction may be the arrangement direction of the first surface 301 and the plurality of blades 200, and the target angle is not 0°.

In the electronic device provided by the embodiments of the present disclosure, the first end 401 of the target component 400 may be connected to the plurality of blades 200, and the second end 402 of the target component 400 may be connected to the second surface 302. This may allow the plurality of blades 200 to be indirectly connected to the fixing component 300 through the target component 400. That is, at least one plurality of blades 200 may be connected to the fixing component 300 through the target component 400, and the portion where the plurality of blades 200 and the target component 400 are connected may be indirectly connected to the same fixing component 300, improving the positional stability of the portion where the plurality of blades 200 and the target component 400 are connected relative to the fixing component 300. When the heat dissipation device rotates to dissipate heat of the heat-generating component 600, the portion where the plurality of blades 200 and the target component 400 are connected may be supported by the fixing component 300 through the target component 400, reducing the displacement of the portion where the plurality of blades 200 and the target component 400 are connected to the overall structure of the heat dissipation device, effectively strengthening the plurality of blades 200's anti-deformation strength and reducing the amount of deformation of the plurality of blades 200 caused by airflow, thereby ensuring the performance of the heat dissipation device. This may ensure the performance of the heat dissipation device, ensure the heat dissipation effect of the heat dissipation device on the heat-generating component 600, and thus ensure the stable operation of the electronic device.

As shown in FIG. 10, the heat dissipation device may have a first side 001 and a second side 002 that are aligned along the axis of the rotor component 100 and face each other. The target position 500 and the heat dissipation device may be aligned perpendicular to the axis of the rotor component 100. The target position 500 may have a third side 003 corresponding to the first side 001 and a fourth side 004 corresponding to the second side 002.

In some embodiments, the target component 400 may be connected to the plurality of blades 200 near the first side 001. Rotation of the plurality of blades 200 may drive airflow toward the fourth side 004 of the target position 500. The heat-generating component 600 may be located on the fourth side 004 of the target position 500. As shown in FIG. 11, the airflow velocity distribution diagram shows that the target component 400 may be connected to the plurality of blades 200 near the first side 001 (e.g., the upper edge of the plurality of blades 200). The red area with faster airflow is near the second side 002 of the heat dissipation device. Since the second side 002 corresponds to the fourth side 004, the heat dissipation device may better dissipate heat from the heat-generating component 600 located on the fourth side 004 of the target position 500.

As shown in FIG. 12, in other embodiments, the target component 400 may be connected to the plurality of blades 200 near the second side 002. As the plurality of blades 200 rotates, it may drive airflow toward the third side 003 of the target position 500, where the heat-generating component 600 is located. As shown in FIG. 13, from the air flow velocity distribution diagram, the target component 400 may be connected to the positions of the plurality of blades 200 close to the second side 002 (such as the lower edge of the plurality of blades 200), and the red area with faster air flow velocity is close to the first side 001 of the heat dissipation device. Since the second side 001 corresponds to the third side 003, the heat dissipation device may be more conducive to dissipating heat for the heat-generating component 600 located on the third side 003 of the target position 500.

The various specific technical features described in the specific embodiments can be combined in any suitable manner without contradiction. For example, different embodiments and technical solutions can be formed by combining different specific technical features. In order to avoid unnecessary repetition, the various possible combinations of the specific technical features in this application will not be described separately.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the present disclosure. Thus, while the present disclosure has been described in detail with reference to the above described embodiments, the present disclosure is not limited to the above described embodiments, but may be embodied in other equivalent forms without departing from the scope of the present disclosure.

What is claimed is:

1. A heat dissipation device, comprising:
a plurality of blades;
a fixing component including a first surface and a second surface, wherein the first surface is adjacent to the second surface and faces the plurality of blades; and
a target component including a first end connected to the plurality of blades and a second end connected to the second surface, wherein:
the first end extends toward the second end along a first direction to form the target component; and
at least a portion of the first direction is arranged at a target angle with respect to a target direction, wherein the target direction is perpendicular to the first surface and the target angle is non-zero.

2. The device according to claim 1, wherein:
at least a portion of the first direction is a curve; and
a curvature of the curve is convex away from the plurality of blades or is convex toward the plurality of blades.

3. The device according to claim 1, wherein:
the first end is connected to an edge of one blade of the plurality of blades facing the fixing component; and
in two adjacent blades of the plurality of blades, there is a distance between the second end of the target component connected to one blade and another blade.

4. The device according to claim 1, wherein:
one blade of the plurality of blades includes a first portion and a second portion arranged in a direction away from a center of the heat dissipation device, and the target component is connected to the second portion.

5. The device according to claim 4, wherein:
a thickness of the first portion is smaller than a thickness of the second portion, wherein a thickness direction is an axial direction of the heat dissipation device;
and/or, the second portion is recessed away from a windward side of the blade, while the first portion is convex toward the windward side of the blade;
and/or, the first surface is connected to second portions of the plurality of blades;
and/or, the target component connects the windward side of the blade to the fixing component, or the target component connects a leeward side of the blade to the fixing component.

6. The device according to claim 4, wherein:
the fixing component is connected to a first position of the second portion, and the target component is connected to a second position of the second portion; and
the first position and the second position are different positions of the second portion and are arranged in a direction toward and away from the center of the heat dissipation device respectively.

7. The device according to claim 1, wherein:
the target component has a guide surface, wherein the guide surface faces an airflow gap between two adjacent blades of the plurality of blades and is not perpendicular to an axis of the heat dissipation device; and
during the rotation of the plurality of blades, the guide surface rotates along an axis of a rotor component, driving fluid in the airflow gap to flow along an axial direction of the heat dissipation device, such that the fluid flows in a direction away from the target component.

8. The device according to claim 1, wherein:
one blade of the plurality of blades includes a first edge and a second edge, wherein an arrangement direction of the first edge and the second edge is an axial direction of the heat dissipation device; and
the fixing component is connected to the first edge of the blade, the second edge of the fan blade, or a middle position of the blade, wherein the middle position is located between the first edge and the second edge.

9. The device according to claim 1, wherein:
the second surface is a surface of the fixing component facing a center of the heat dissipation device, and the target component connects a portion of one blade of the plurality of blades located between the fixing component and the center of the heat dissipation device to the second surface; or
the second surface is a surface of the fixing component facing away from the center of the heat dissipation device, and the target component connects a portion of the blade located on the fixing component away from the center of the heat dissipation device to the second surface; or
the second surface includes a first sub-surface of the fixing component facing the center of the heat dissipation device and a second sub-surface of the fixing component facing away from the center of the heat dissipation device, and the target component includes a first reinforcement and a second reinforcement, wherein the first reinforcement connects a portion of one blade of the plurality of blades located between the fixing component and the center of the heat dissipation device to the first sub-surface and the second reinforcement connects a portion of the blade located on the fixing component away from the center of the heat dissipation device to the second sub-surface.

10. The device according to claim 1, wherein:
the first surface is connected to the plurality of blades, and a rounded structure is provided at a connection position between the first surface and one blade of the plurality of blades, wherein the target component is connected to the rounded structure.

11. The device according to claim 1, wherein:
the heat dissipation device has a first side and a second side arranged along an axis of the heat dissipation device and facing each other;
the target position is arranged perpendicular to the axis of the heat dissipation device; and
the target position has a third side corresponding to the first side and a fourth side corresponding to the second side,
wherein:
the target component is connected to the plurality of blades near the first side, and during rotation, the plurality of blades drives airflow to flow toward an orientation area of the fourth side of the target position; or
the target component is connected to the fan blade near the second side, and during rotation, the plurality of blades drives the airflow toward the third side of the target position.

12. The device according to claim 1, further comprising a rotor component capable of rotating along an axis thereof, wherein:
the plurality of blades is arranged along a circumference of the rotor component; or
the plurality of blades includes first blades and second fan blades, wherein the first blades connect the rotor component to the fixing component and the second blades connect the fixing component.

13. An electronic device, comprising a heat-generating component and a heat dissipation device for dissipating heat on the heat-generating component, wherein:
the heat dissipation device includes:
a plurality of blades;
a fixing component having a first surface and a second surface, wherein the first surface is adjacent to the second surface and faces the plurality of blades; and
a target component having a first end connected to the plurality of blades and a second end connected to the second surface, wherein:
the first end extends toward the second end along a first direction to form the target component;
at least a portion of the first direction is arranged at a target angle with respect to a target direction, wherein the target direction is an arrangement direction of the first surface along with the plurality of blades; and
the target angle is non-zero.

14. The device according to claim 13, wherein:
the heat dissipation device has a first side and a second side arranged along an axis of the heat dissipation device and facing each other;
the target position is arranged perpendicular to the axis of the heat dissipation device; and
the target position has a third side corresponding to the first side and a fourth side corresponding to the second side,
wherein:
the target component is connected to the plurality of blades near the first side, and during rotation, the plurality of blades drives airflow to flow toward an orientation area of the fourth side of the target position; or
the target component is connected to the fan blade near the second side, and during rotation, the plurality of blades drives the airflow toward the third side of the target position.

15. The device according to claim 13, wherein:
at least a portion of the first direction is a curve; and
a curvature of the curve is convex away from the plurality of blades or is convex toward the plurality of blades.

16. The device according to claim 13, wherein:
the first end is connected to an edge of one blade of the plurality of blades facing the fixing component; and
in two adjacent blades of the plurality of blades, there is a distance between the second end of the target component connected to one blade and another blade.

17. The device according to claim 13, wherein:
one blade of the plurality of blades includes a first portion and a second portion arranged in a direction away from a center of the heat dissipation device, and the target component is connected to the second portion.

18. The device according to claim 17, wherein:
a thickness of the first portion is smaller than a thickness of the second portion, wherein a thickness direction is an axial direction of the heat dissipation device;
and/or, the second portion is recessed away from a windward side of the blade, while the first portion is convex toward the windward side of the blade;
and/or, the first surface is connected to second portions of the plurality of blades;
and/or, the target component connects the windward side of the blade to the fixing component, or the target component connects a leeward side of the blade to the fixing component.

19. The device according to claim 17, wherein:
the fixing component is connected to a first position of the second portion, and the target component is connected to a second position of the second portion; and
the first position and the second position are different positions of the second portion and are arranged in a direction toward and away from the center of the heat dissipation device respectively.

20. The device according to claim 13, wherein:
the target component has a guide surface, wherein the guide surface faces an airflow gap between two adjacent blades of the plurality of blades and is not perpendicular to an axis of the heat dissipation device; and
during the rotation of the plurality of blades, the guide surface rotates along an axis of a rotor component, driving fluid in the airflow gap to flow along an axial direction of the heat dissipation device, such that the fluid flows in a direction away from the target component.
